(19) United States
(12) Patent Application Publication
(10) Pub. No.: US 2025/0233597 A1
(43) Pub. Date: Jul. 17, 2025

(54) ADC CALIBRATION FOR MICROSCOPY

(71) Applicant: ASML Netherlands B.V., Veldhoven (NL)

(72) Inventors: Hindrik Willem MOOK, The Hague (NL); Dhara DAVE, Delfgauw (NL); Antri STYLIANOU, Pijnacker (NL); Vincent Claude BEUGIN, Nootdrop (NL); Pieter Lucas BRANDT, Son (NL); Diego MARTINEZ NEGRETE GASQUE, Delft (NL)

(73) Assignee: ASML Netherlands B.V., Veldhoven (NL)

(21) Appl. No.: 19/170,979

(22) Filed: Apr. 4, 2025

(30) Foreign Application Priority Data
Oct. 7, 2022 (EP) 22200243.8

(51) Int. Cl. H03M 1/10; H01J 37/22; H01J 37/24

(52) U.S. Cl. CPC H03M 1/1028; H01J 37/222; H01J 37/24; H01J 2237/221

(57) ABSTRACT

A method of calibrating analog-to-digital converters, ADCs, of a charged particle-optical device comprises: providing, for each of the ADCs, image data of charged particles detected from a sample output by the ADC; calculating, for each of the ADCs, at least one statistical value from a distribution of the image data output by the ADC; and changing at least one setting of at least one of the ADCs based on the calculated at least one statistical values so as to compensate for any mismatch between the at least one statistical value of the ADCs.

### CROSS-REFERENCE TO RELATED APPLICATIONS

This application claims priority of International application PCT/EP2023/076057, filed on 21 Sep. 2023, which claims priority of EP Application Serial No. 22200243.8, filed on 7 Oct. 2022. These applications are incorporated herein by reference in their entireties.

### TECHNICAL FIELD

The embodiments provided herein disclose a method for processing image data of charged particles detected from a sample, a method of enhancing image data, a method of calibrating analog-to-digital converters, non-transitory computer readable media and charged particle-optical devices.

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed. As the physical sizes of IC components continue to shrink, and their structures continue to become more complex, accuracy and throughput in defect detection and inspection become more important. The overall image quality depends on a combination of high secondary-electron and backscattered-electron signal detection efficiencies, among others. Backscattered electrons have higher emission energy to escape from deeper layers of a sample, and therefore, their detection may be desirable for imaging of complex structures such as buried layers, nodes, high-aspect-ratio trenches, or holes of 3D NAND devices. For applications such as overlay metrology, it may be desirable to obtain high quality imaging and efficient collection of surface information from secondary electrons and buried layer information from backscattered electrons, simultaneously, highlighting a need for using multiple electron detectors in a SEM. Although multiple electron detectors in various structural arrangements may be used to maximize collection and detection efficiencies of secondary and backscattered electrons individually, the combined detection efficiencies remain low, and therefore, the image quality achieved may be inadequate for high accuracy and high throughput defect inspection and metrology of two-dimensional and three-dimensional structures.

### SUMMARY

In some embodiments, a charged particle-optical device is configured to direct a charged particle beam towards a sample location so that signal charged particles are generated in response to the charged particle beam, the charged particle-optical device comprising: an array of sensing elements configured to generate electrical signals in response to incident signal charged particles from the sample location; a plurality of analog-to-digital converters, ADCs, configured to convert the electrical signals into image data; and a controller configured to process the image data by: receiving, for each ADC, at least one statistical value that was calculated from a distribution of the image data output by the ADC; and changing at least one setting of the at least one ADC based on a distribution adjustment that was determined as required for the calculated at least one statistical values to match across the distributions of image data output by the ADCs.

In some embodiments, a method is provided for processing image data of charged particles detected from a sample output by a plurality of analog-to-digital converters, ADCs, the method comprising: calculating, for each of the ADCs, at least one statistical value from a distribution of the image data output by the ADC; and determining at least one distribution adjustment required for the calculated at least one statistical values to match across the distributions of image data output by the ADCs.

Other advantages of the embodiments of the present disclosure will become apparent from the following description taken in conjunction with the accompanying drawings wherein are set forth, by way of illustration and example, certain embodiments of the present invention.

### BRIEF DESCRIPTION OF FIGURES

The above and other aspects of the present disclosure will become more apparent from the description of exemplary embodiments, taken in conjunction with the accompanying drawings in which:

FIG. 1 is a schematic diagram illustrating an exemplary electron beam inspection (EBI) system, consistent with embodiments of the present disclosure.

FIG. 2A, FIG. 2B, and FIG. 2C are schematic diagrams illustrating exemplary electron beam tools, consistent with embodiments of the present disclosure that may be a part of the exemplary electron beam inspection system of FIG. 1.

FIG. 3 is an exemplary SEM image before the image is enhanced.

FIG. 4 is an exemplary SEM image after the SEM image of FIG. 3 has been enhanced, consistent with embodiments of the present disclosure.

FIG. 5 is a graph showing the relationship between image data output by a reference analog-to-digital converter (ADC) and image data output by another ADC.

FIG. 6 is a diagram illustrating pre-calibration of ADCs, consistent with embodiments of the present disclosure.

FIG. 7 is a process flow chart representing an exemplary method of enhancing image data, consistent with embodiments of the present disclosure.

FIG. 8 is a process flow chart representing an exemplary method of calibrating ADCs, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations. Instead, they are merely examples of apparatuses and methods consistent with aspects related to the disclosed embodiments as recited in the appended claims. For example, although some embodiments are described in the context of utilizing electron beams, the disclosure is not so limited. Other types of charged particle beams may be similarly applied.

One component of improving yield is monitoring the chip making process to ensure that it is producing a sufficient number of functional integrated circuits. One way to monitor the process is to inspect the chip circuit structures at various stages of their formation. Inspection can be carried out using an SEM. An SEM can be used to image these extremely small structures, in effect, taking a “picture” of the structures. The image can be used to determine if the structure was formed properly and also if it was formed in the proper location. If the structure is defective, then the process can be adjusted so the defect is less likely to recur. It may be desirable to have higher throughput for defect detection and inspection processes to meet the requirements of IC manufacturers.

During inspection, the SEM produces signals for different locations on the sample (e.g. wafer). These signals are converted by ADCs into brightness values for the pixels that build up the “picture” of the structures. A single ADC may not be able to keep up with the rate at which the SEM produces the signals and so a few ADCs may each take a different portion of the signal and convert its portion of the signal into a brightness value. For example if there are four ADCs, then each ADC may convert the signal for every fourth location on the wafer. The ADCs may have slightly different characteristics. This may lead to a systematic variation between pixels with brightness values from the different ADCs. For example one ADC may generally output brightness values slightly higher (leading to slightly brighter pixels in the “picture”) than the others for a same signal. The ADCs can be calibrated relative to each other by adjusting their settings so that the distributions of brightness values that they output for a given “picture” match each other. This works because in general one would expect that within a given wafer the locations that have brightness values output by the different ADCs should have similar distributions, for example similar average brightness and similar variance. Further, locations on the wafer with similar characteristics (e.g., a memory array) can be selected for use. Although the ADCs are in fact outputting brightness values for different locations of the wafer, the large number of locations and/or selecting locations with similar characteristics means that the brightness difference due to the structures on the wafer generally average out over the image.

Relative dimensions of components in drawings may be exaggerated for clarity. Within the following description of drawings, the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

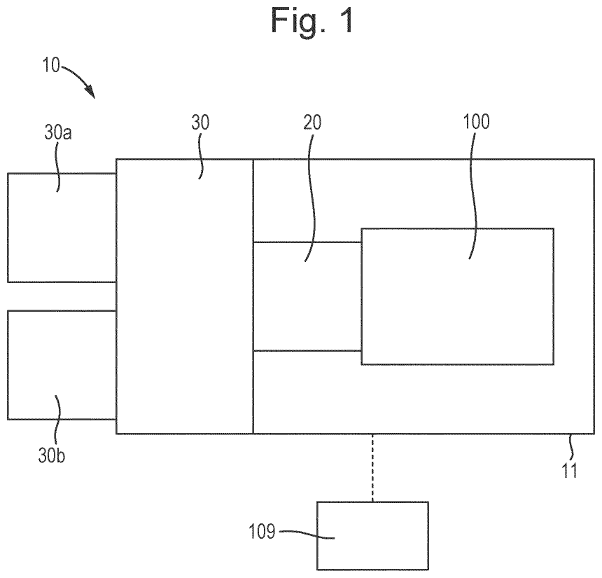

Reference is now made to FIG. 1, which illustrates an exemplary EBI system 10 that may include a detector, consistent with embodiments of the present disclosure. EBI system 10 may be used for imaging. As shown in FIG. 1, EBI system 10 includes a main chamber 11 a load/lock chamber 20, an electron beam tool 100, and an equipment front end module (EFEM) 30. Electron beam tool 100 is located within main chamber 11. EFEM 30 includes a first loading port 30a and a second loading port 30b. EFEM 30 may include additional loading port(s). First loading port 30a and second loading port 30b receive wafer front opening unified pods (FOUPs) that contain wafers (e.g., semiconductor wafers or wafers made of other material(s)) or samples to be inspected (wafers and samples may be collectively referred to as “samples” herein).

One or more robotic arms (not shown) in EFEM 30 may transport the wafers to load/lock chamber 20. Load/lock chamber 20 is connected to a load/lock vacuum pump system (not shown) which removes gas molecules in load/lock chamber 20 to reach a first pressure below the atmospheric pressure. After reaching the first pressure, one or more robotic arms (not shown) may transport the wafer from load/lock chamber 20 to main chamber 11. Main chamber 11 is connected to a main chamber vacuum pump system (not shown) which removes gas molecules in main chamber 11 to reach a second pressure below the first pressure. After reaching the second pressure, the wafer is subject to inspection by electron beam tool 100. Electron beam tool 100 may be a single-beam system or a multi-beam system. A controller 109 is electronically connected to electron beam tool 100 and may be electronically connected to other components as well. Controller 109 may be a computer configured to execute various controls of EBI system 10. While controller 109 is shown in FIG. 1 as being outside of the structure that includes main chamber 11, load/lock chamber 20, and EFEM 30, it is appreciated that controller 109 can be part of the structure.

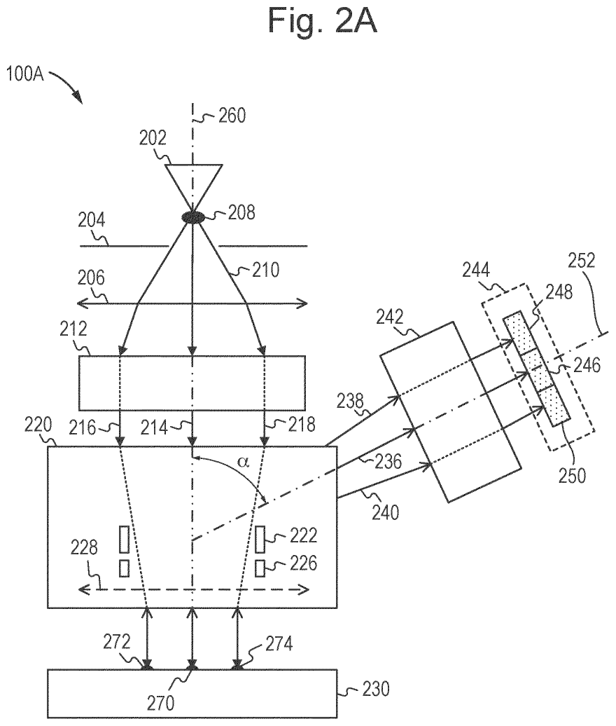

FIG. 2A illustrates a charged particle beam apparatus in which an inspection system may comprise a multi-beam inspection tool that uses multiple primary electron beamlets to simultaneously scan multiple locations on a sample.

As shown in FIG. 2A, an electron beam tool 100A (also referred to herein as an electron beam apparatus 100A or an electron-optical device) may comprise an electron source 202, a gun aperture 204, a condenser lens 206, a primary electron beam 210 emitted from electron source 202, a source conversion unit 212, a plurality of beamlets 214, 216, and 218 of primary electron beam 210, a primary projection optical system 220, a wafer stage (not shown in FIG. 2A), multiple secondary electron beams 236, 238, and 240, a secondary optical system 242, and an electron detection device 244. Electron source 202 may generate primary particles, such as electrons of primary electron beam 210. A controller, image processing system, and the like may be coupled to electron detection device 244. Primary projection optical system 220 may comprise a beam separator 222, deflection scanning unit 226, and objective lens 228. Electron detection device 244 may comprise detection sub-regions 246, 248, and 250.

Electron source 202, gun aperture 204, condenser lens 206, source conversion unit 212, beam separator 222, deflection scanning unit 226, and objective lens 228 may be aligned with a primary optical axis 260 of electron beam apparatus 100A. Secondary optical system 242 and electron detection device 244 may be aligned with a secondary optical axis 252 of electron beam apparatus 100A.

Electron source 202 may comprise a cathode, an extractor or an anode, wherein primary electrons can be emitted from the cathode and extracted or accelerated to form a primary electron beam 210 with a crossover (virtual or real) 208. Primary electron beam 210 can be visualized as being emitted from crossover 208. Gun aperture 204 may block off peripheral electrons of primary electron beam 210 to reduce size of probe spots 270, 272, and 274.

Source conversion unit 212 may comprise an array of image-forming elements (not shown in FIG. 2A) and an array of beam-limit apertures (not shown in FIG. 2A). An example of source conversion unit 212 may be found in U.S. Pat. No. 9,691,586; U.S. Publication No. 2017/0025243; and International Application No. PCT/EP2017/084429, all of which are incorporated by reference in their entireties. The array of image-forming elements may comprise an array of micro-deflectors or micro-lenses. The array of image-forming elements may form a plurality of parallel images (virtual or real) of crossover 208 with a plurality of beamlets 214, 216, and 218 of primary electron beam 210. The array of beam-limit apertures may limit the plurality of beamlets 214, 216, and 218.

Condenser lens 206 may focus primary electron beam 210. The electric currents of beamlets 214, 216, and 218 downstream of source conversion unit 212 may be varied by adjusting the focusing power of condenser lens 206 or by changing the radial sizes of the corresponding beam-limit apertures within the array of beam-limit apertures. Condenser lens 206 may be a moveable condenser lens that may be configured so that the position of its first principle plane is movable. The movable condenser lens may be configured to be magnetic, which may result in off-axis beamlets 216 and 218 landing on the beamlet-limit apertures with rotation angles. The rotation angles change with the focusing power and the position of the first principal plane of the movable condenser lens. In some embodiments, the moveable condenser lens may be a moveable anti-rotation condenser lens, which involves an anti-rotation lens with a movable first principal plane. A moveable condenser lens is further described in U.S. Publication No. 2017/0025241, which is incorporated by reference in its entirety.

Objective lens 228 may focus beamlets 214, 216, and 218 onto a wafer 230 (i.e. a sample) for inspection and may form a plurality of probe spots 270, 272, and 274 on the surface of wafer 230.

Beam separator 222 may be a beam separator of Wien filter type generating an electrostatic dipole field and a magnetic dipole field. In some embodiments, if they are applied, the force exerted by electrostatic dipole field on an electron of beamlets 214, 216, and 218 may be equal in magnitude and opposite in direction to the force exerted on the electron by magnetic dipole field. Beamlets 214, 216, and 218 can therefore pass straight through beam separator 222 with zero deflection angle. However, the total dispersion of beamlets 214, 216, and 218 generated by beam separator 222 may also be non-zero. Beam separator 222 may separate secondary electron beams 236, 238, and 240 from beamlets 214, 216, and 218 and direct secondary electron beams 236, 238, and 240 towards secondary optical system 242.

Deflection scanning unit 226 may deflect beamlets 214, 216, and 218 to scan probe spots 270, 272, and 274 over a surface area of wafer 230. In response to incidence of beamlets 214, 216, and 218 at probe spots 270, 272, and 274, secondary electron beams 236, 238, and 240 may be emitted from wafer 230. Secondary electron beams 236, 238, and 240 may comprise electrons with a distribution of energies including secondary electrons and backscattered electrons. Secondary optical system 242 may focus secondary electron beams 236, 238, and 240 onto detection sub-regions 246, 248, and 250 of electron detection device 244. Detection sub-regions 246, 248, and 250 may be configured to detect corresponding secondary electron beams 236, 238, and 240 and generate corresponding signals used to reconstruct an image of surface area of wafer 230.

Although FIG. 2A shows an example of electron beam tool 100 as a multi-beam tool that uses a plurality of beamlets, embodiments of the present disclosure are not so limited. For example, electron beam tool 100 may also be a single-beam tool that uses only one primary electron beam to scan one location on a wafer at a time.

As shown in FIG. 2B, an electron beam tool 100B (also referred to herein as electron beam apparatus 100B) may be a single-beam inspection tool that is used in EBI system 10. Electron beam apparatus 100B includes an electron-optical device configured to project electrons towards a sample location (i.e. where the wafer is) and a wafer holder 136 supported by motorized stage 134 to hold a wafer 150 (i.e. a sample) to be inspected. Electron beam tool 100B includes an electron emitter, which may comprise a cathode 103, an anode 121, and a gun aperture 122. Electron beam tool 100B further includes a beam limit aperture 125, a condenser lens 126, a column aperture 135, an objective lens assembly 132, and a detector 144. Objective lens assembly 132, in some embodiments, may be a modified SORIL lens, which includes a pole piece 132a, a control electrode 132b, a deflector 132c, and an exciting coil 132d. In an imaging process, an electron beam 161 emanating from the tip of cathode 103 may be accelerated by anode 121 voltage, pass through gun aperture 122, beam limit aperture 125, condenser lens 126, and be focused into a probe spot 170 by the modified SORIL lens and impinge onto the surface of wafer 150. Probe spot 170 may be scanned across the surface of wafer 150 by a deflector, such as deflector 132c or other deflectors in the SORIL lens. Secondary or scattered primary particles, such as secondary electrons or scattered primary electrons emanated from the wafer surface may be collected by detector 144 to determine intensity of the beam and so that an image of an area of interest on wafer 150 may be reconstructed.

There may also be provided an image processing system 199 that includes an image acquirer 120, a storage 130, and controller 109. Image acquirer 120 may comprise one or more processors. For example, image acquirer 120 may comprise a computer, server, mainframe host, terminals, personal computer, any kind of mobile computing devices, and the like, or a combination thereof. Image acquirer 120 may connect with detector 144 of electron beam tool 100B through a medium such as an electrical conductor, optical fiber cable, portable storage media, IR, Bluetooth, Internet, wireless network, wireless radio, or a combination thereof. Image acquirer 120 may receive a signal from detector 144 and may construct an image. Image acquirer 120 may thus acquire images of wafer 150. Image acquirer 120 may also perform various post-processing functions, such as generating contours, superimposing indicators on an acquired image, and the like. Image acquirer 120 may be configured to perform adjustments of brightness and contrast, etc. of acquired images. Storage 130 may be a storage medium such as a hard disk, random access memory (RAM), cloud storage, other types of computer readable memory, and the like. Storage 130 may be coupled with image acquirer 120 and may be used for saving scanned raw image data as original images, and post-processed images. Image acquirer 120 and storage 130 may be connected to controller 109. In some embodiments, image acquirer 120, storage 130, and controller 109 may be integrated together as one electronic control unit.

In some embodiments, image acquirer 120 may acquire one or more images of a sample based on an imaging signal received from detector 144. An imaging signal may correspond to a scanning operation for conducting charged particle imaging. An acquired image may be a single image comprising a plurality of imaging areas that may contain various features of wafer 150. The single image may be stored in storage 130. Imaging may be performed on the basis of imaging frames.

The condenser and illumination optics of the electron beam tool may comprise or be supplemented by electromagnetic quadrupole electron lenses. For example, as shown in FIG. 2B, electron beam tool 100B may comprise a first quadrupole lens 148 and a second quadrupole lens 158. In some embodiments, the quadrupole lenses are used for controlling the electron beam. For example, first quadrupole lens 148 can be controlled to adjust the beam current and second quadrupole lens 158 can be controlled to adjust the beam spot size and beam shape.

FIG. 2B illustrates a charged particle beam apparatus in which an inspection system may use a single primary beam that may be configured to generate secondary electrons by interacting with wafer 150. Detector 144 may be placed along optical axis 105, as in the example shown in FIG. 2B. The primary electron beam may be configured to travel along optical axis 105. Accordingly, detector 144 may include a hole at its center so that the primary electron beam may pass through to reach wafer 150. However, some embodiments may use a detector placed off-axis relative to the optical axis along which the primary electron beam travels. For example, as in the example shown in FIG. 2A, beam separator 222 may be provided to direct secondary electron beams toward a detector placed off-axis. Beam separator 222 may be configured to divert secondary electron beams by an angle α.

Another example of a charged particle beam apparatus will now be discussed with reference to FIG. 2C. Electron beam tool 100C (also referred to herein as an electron beam apparatus 100C or an electron-optical device) may be an example of electron beam tool 100 and may be similar to electron beam tool 100A shown in FIG. 2A.

As shown in FIG. 2C, beam separator 222 may be a beam separator of Wien filter type generating an electrostatic dipole field and a magnetic dipole field. In some embodiments, if they are applied, the force exerted by electrostatic dipole field on an electron of beamlets 214, 216, and 218 may be equal in magnitude and opposite in direction to the force exerted on the electron by magnetic dipole field. Beamlets 214, 216, and 218 can therefore pass straight through beam separator 222 with zero deflection angle. However, the total dispersion of beamlets 214, 216, and 218 generated by beam separator 222 may also be non-zero. For a dispersion plane 224 of beam separator 222, FIG. 2C shows dispersion of beamlet 214 with nominal energy V0 and an energy spread ΔV into beamlet portions 262 corresponding to energy V0, beamlet portion 264 corresponding to energy V0+ΔV/2, and beamlet portion 266 corresponding to energy V0−ΔV/2. The total force exerted by beam separator 222 on an electron of secondary electron beams 236, 238, and 240 can be non-zero. Beam separator 222 may separate secondary electron beams 236, 238, and 240 from beamlets 214, 216, and 218 and direct secondary electron beams 236, 238, and 240 towards secondary optical system 242.

A semiconductor electron detector (sometimes called a “PIN detector”) may be used in apparatus 100 in EBI system 10. EBI system 10 may be a high-speed wafer imaging SEM including an image processor. An electron beam generated by EBI system 10 may irradiate the surface of a sample or may penetrate the sample. EBI system 10 may be used to image a sample surface or structures under the surface, such as for analyzing layer alignment. In some embodiments, EBI system 10 may detect and report process defects relating to manufacturing semiconductor wafers by, for example, comparing SEM images against device layout patterns, or SEM images of identical patterns at other locations on the wafer under inspection. A PIN detector may include a silicon PIN diode that may operate with negative bias. A PIN detector may be configured so that incoming electrons generate a relatively large and distinct detection signal. In some embodiments, a PIN detector may be configured so that an incoming electron may generate a number of electron-hole pairs while a photon may generate just one electron-hole pair. A PIN detector used for electron counting may have numerous differences as compared to a photodiode used for photon detection, as shall be discussed as follows.

In some embodiments, the detector (e.g. the electron detection device 244 shown in FIG. 2A or FIG. 2C or the detector 144 shown in FIG. 2B) comprises a plurality of detector elements (e.g. detection sub-regions 246, 248, and 250). The detector elements may be connected to one or more circuit layers. A circuit layer of the detector may comprise circuitry having amplification and/or digitation functions, e.g. it may comprise an amplification circuit. A circuit layer may comprise one or more trans impedance amplifiers (TIAs) and one or more ADCs. A detector element and an associated feedback resistor may be connected to the TIA and ADC. One or more digital signal lines may be connected from the ADC for transferring digital signals, e.g. to the image acquirer 120 shown in FIG. 2B.

In some embodiments, a detector may communicate with a controller that controls a charged particle beam system. The controller may instruct components of the charged particle beam system to perform various functions, such as controlling a charged particle source to generate a charged particle beam and controlling a deflector to scan the charged particle beam. The controller may also perform various other functions such as adjusting a sampling rate of a detector, resetting a sensing element, or performing image processing. In some embodiments, the controller is configured to control settings of the ADCs. The controller may comprise a storage that is a storage medium such as a hard disk, random access memory (RAM), other types of computer readable memory, and the like. The storage may be used for saving scanned raw image data as original images, and post-processed images. A non-transitory computer readable medium may be provided that stores instructions for a processor of controller 109 to carry out charged particle beam detection, sampling period determination, image processing, or other functions and methods consistent with the present disclosure. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a ROM, a PROM, and EPROM, a FLASH-EPROM or any other flash memory, NVRAM, a cache, a register, any other memory chip or cartridge, and networked versions of the same.

Block diagrams in the figures may illustrate the architecture, functionality, and operation of possible implementations of systems, methods, and computer hardware/software products according to various exemplary embodiments of the present disclosure. In this regard, each block in a schematic diagram may represent certain arithmetical or logical operation processing that may be implemented using hardware such as an electronic circuit. Blocks may also represent a module, segment, or portion of code that comprises one or more executable instructions for implementing the specified logical functions. It should be understood that in some alternative implementations, functions indicated in a block may occur out of the order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

An electron beam tool 100 may scan a sample (e.g. a wafer). The electron beam tool 100 may scan one or more electron beams across the surface of the sample. A detector of the electron beam tool 100 is configured to detect signal electrons from the sample. By detecting the signal electrons, information about the sample can be obtained. The signal electrons may include backscattered electrons and/or secondary electrons.

During the scan, the electron beam tool 100 may scan sequential locations of the sample. The sequential locations may be adjacent to each other at the surface of the sample. The sample may be scanned row by row. Each location may correspond to a pixel in an image that can be constructed from the data obtained by the electron beam tool 100 during the scan.

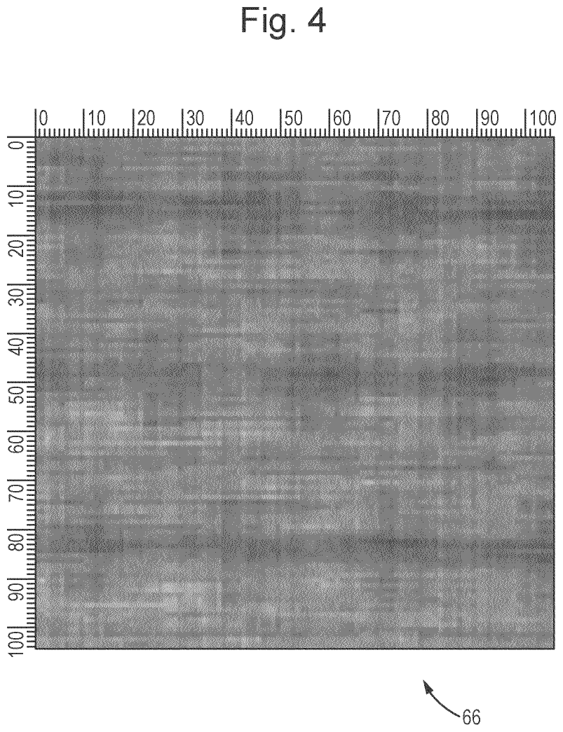

As shown in FIG. 6, in some embodiments, the detector 144 comprises detector elements 145. The detector elements 145 may generate analog signals indicative of signal electrons that have been detected. Each analog signal may, for example, be dependent on the number of signal electrons detected from a location on the sample. The analog signals may be transferred to an ADC configured to convert the analog signal into a digital signal.

The digital signal may be subsequently used as a brightness value for a pixel in an image formed from the data obtained by the electron beam tool 100. The image may be an image of the surface of the sample. For example, if few electrons are detected from a location, then the digital signal may correspond to a low brightness value such that the pixel corresponding to that location appears dark in an image of the sample. If many electrons are detected from a location, then the digital signal may correspond to a high brightness level such that a pixel corresponding to that location appears bright in an image of the sample. Alternatively, a lower number of detected electrons may be correlated with an increased brightness value. It may be that no image is generated based on the data. The digital signals output by the ADCs may be analysed and/or processed without the image being generated.

The electron beam tool 100 may scan a large number of locations of the sample. The electron beam tool 100 may scan locations of the sample at a high rate. As shown in FIG. 6, in some embodiments, a plurality of ADCs 51-54 are provided. The analog signals from the detector elements 1445 may be provided to the ADCs 51-54. A plurality of ADCs 51-54 can convert analog signals into digital signals at a higher rate compared to only one ADC. In some embodiments, analog signals from the detector elements 145 are provided to the ADCs 51-54 according to a repeated sequence of the ADCs 51-54. For example, when four ADCs are provided, then each ADC may convert the analog signal indicative of electrons detected from every fourth location scanned by the electron beam tool 100. Every fourth location may correspond to every fourth pixel in an image generated from the collected data.

It is not essential for the number of ADCs to be four. In alternative embodiments, the number of ADCs may be two, three or five or more. A larger number of ADCs may allow a higher rate of converting analog signals from the detector elements 145. A smaller number of ADC may reduce the possibility of discrepancies between the ADCs leading to systematic artifacts in the image data output by the ADCs.

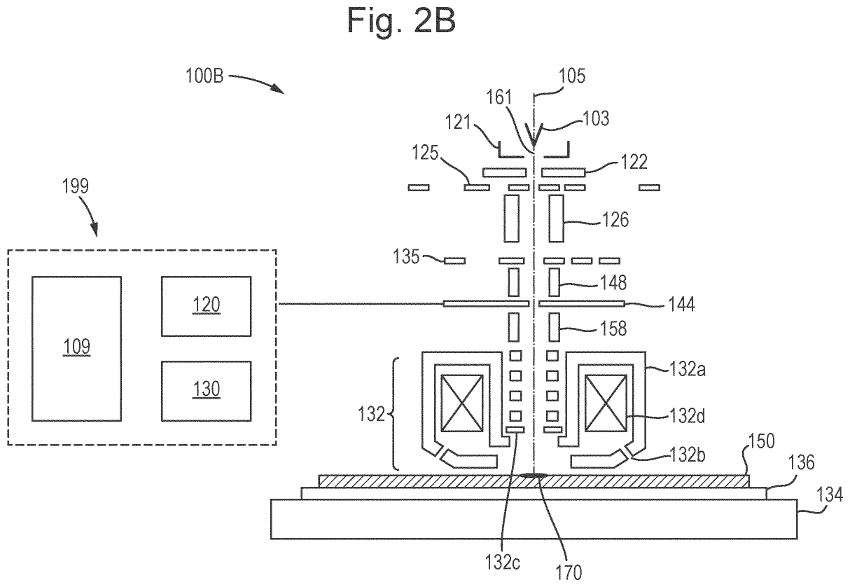

FIG. 3 shows an unenhanced SEM image 60. The unenhanced SEM image 60 comprises a plurality of pixels 65. Each pixel 65 has a given brightness value. The brightness value may be referred to as a grey-scale level. In some embodiments, the brightness value can take any value within a range of discrete values. For example, in some embodiments, the brightness value is on a scale from 0 to 255. The grey scale may have a different number of possible values, for example 64, 128, 512 or 1024.

In the unenhanced SEM image 60, every fourth pixel 65 corresponds to data output by the same ADC. In the unenhanced SEM image 60 shown in FIG. 3, each row has as its left-most pixel a pixel that corresponds to data from the same ADC. In some embodiments, each row contains a number of pixels divisible by four. Each column of pixels is from the same ADC. This is indicated in the bottom left-hand corner of the unenhanced SEM image 60. Two columns are indicated as comprising first pixels 61 having brightness values based on digital signals output by a first ADC 51. Another two columns are indicated as comprising second pixels 62 with brightness values based on digital signals output by a second ADC 52. Two further columns are indicated as comprising third pixels 63 having brightness values based on digital signals output by a third ADC 53. Two further columns are indicated as comprising fourth pixels 64 with brightness values based on digital signals output by a fourth ADC 54.

As shown in the unenhanced SEM image 60, artifacts may appear. For example, column artifacts are shown in the unenhanced SEM image 60 of FIG. 3. Such artifacts may be the result of discrepancies between the different ADCs 51-54. The ADCs 51-54 may not perfectly match each other. The different ADCs 51-54 may give different digital signals (different grey level values) for the same analog signal (electron signal input). For example, in the unenhanced SEM image 60 shown in FIG. 3, it appears that the third pixels 63 are generally systematically darker than the first pixels 61, the second pixels 62 or the fourth pixels 64. This may indicate that the third ADC 53 systematically gives lower grey level values for the same electron signal input compared to the first ADC 51, the second ADC 52 or the further ADC 54.

In some embodiments, a method is for processing image data. The image data may be of charge particles (e.g. electrons) detected from a sample. The image data may be output by a plurality of ADCs 51-54. As mentioned above, it may be that an image is formed from the image data. Alternatively, it may be that no image is formed from the image data. The image data is considered image data regardless of whether or not an image is actually generated from it because an image could be generated from it. The image would correspond to a region of the surface of the sample.

As mentioned above, during a scan of the sample, the ADCs 51-54 output digital signals corresponding to different locations of the sample. Each of the ADCs 51-54 outputs a plurality of digital signals. For example, in order to form the unenhanced SEM image 60 shown in FIG. 3, each of the ADCs 51-54 outputs a number of digital signals corresponding to one quarter of the number of pixels in the unenhanced SEM image 60. The digital signals output by a given ADC may correspond to different brightness values. The digital signals output by a given ADC may be referred to as a distribution of image data.

In some embodiments, the method comprises calculating, for each of the ADCs 51-54, at least one statistical value from a distribution of the image data output by the ADC. As explained in more detail below, the statistical value may be an average (e.g. an average such as a mean) of the brightness values of the distribution of the image data. The at least one statistical value may comprise a standard deviation (a sigma value) of the brightness values of the distribution of the image data. For example, the average and standard deviation of the digital signals output by the first ADC 51 may be calculated. Similarly, the average and standard deviation of the digital signals output by each of the second ADC 52, the third ADC 53 and the fourth ADC 54 may be calculated.

It is not essential to calculate both the average and the standard deviation of the distribution of the image data. In some embodiments, the averages calculated without calculating the standard deviation. In a further alternative, the standard deviation is calculated without calculating the average. Other statistical values may be calculated, particularly statistical values that are a measure of the amount of variation or dispersion of the digital signals or a statistical value that can be taken as representative of the digital signals.

In some embodiments, the method comprises determining at least one distribution adjustment required for the calculated at least one statistical values to match across the distributions of image data output by the ADCs 51-54. For example, as mentioned above, it appears from the unenhanced SEM image 60 shown in FIG. 3 that the average for the image data output by the third ADC 53 may be lower than the averages of the image data output by the other ADCs 51, 52, 54. In order for the averages to match across the distributions of image data output by the ADCs 51-54, it may be necessary to increase the values of the image data output by the third ADC 53 (and/or decrease the values of the image data output by the other ADCs 51, 52, 54).

It may be determined that a distribution adjustment required for the calculated averages to match across the distributions of image data output by the ADCs 51-54 is an increase of values of image data output by the third ADC 53. In some embodiments, the distribution adjustment comprises an increase or decrease in average of the distribution of image data output by one or more of the ADCs. In some embodiments, the at least one distribution adjustment comprises an increase or decrease in standard deviation of the distribution of image data output by one or more of the ADCs.

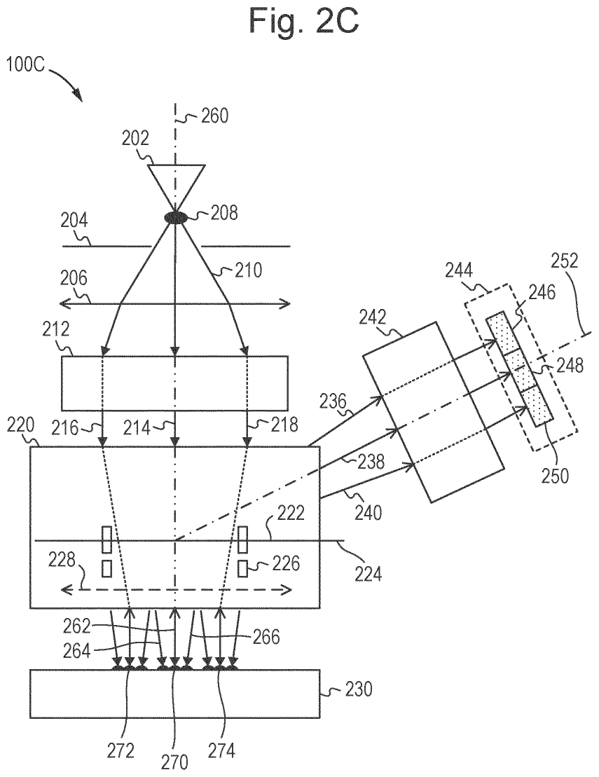

At least some embodiments of the present disclosure are expected to improve image data that can be used to image the sample. By matching a given statistical value across the distributions of image data output by different ADCs 51-54, the information from a scan can be used to correct the original data from the separate ADCs 51-54. Calculating the statistical value and determining one or more distribution adjustments required to match the statistical values across the distributions may be performed simply. The determination of the distribution adjustments is effective for improving the original data. For example, FIG. 4 is an enhanced SEM image 66. The enhanced SEM image 66 is formed from an enhanced version of the same image data that was used to form the unenhanced SEM image 60 shown in FIG. 3. As can be seen from a comparison between FIG. 3 and FIG. 4, artifacts are reduced. In particular, the prominent column artifacts shown in FIG. 3 are reduced or not present in FIG. 4.

In some embodiments, the method can be used for post-processing correction of image data (e.g. SEM image data) that have already been acquired. Additionally or alternatively, the method can be used for adjusting one or more calibration settings for the ADCs 51-54.

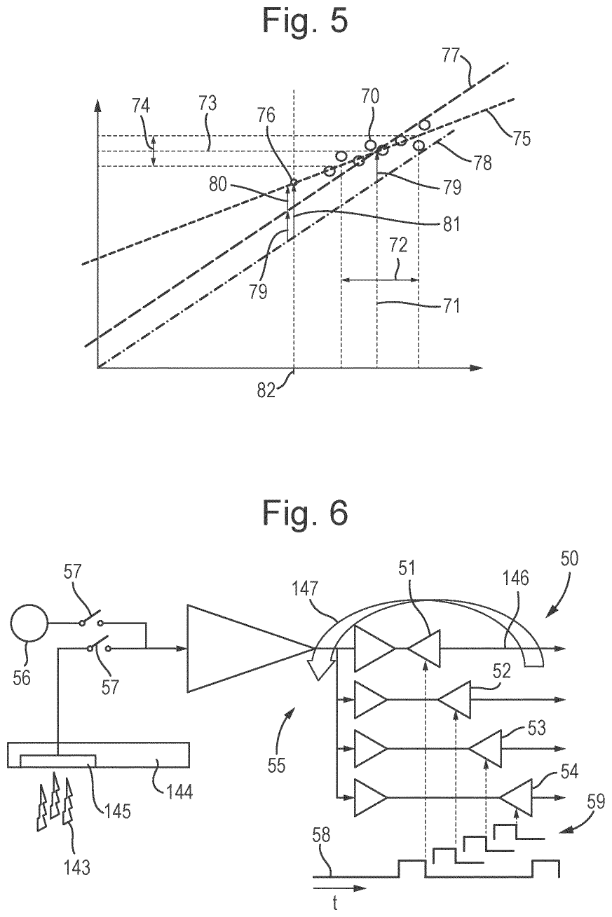

FIG. 7 is a process flow chart representing an exemplary method of enhancing image data. In some embodiments, the method comprises pre-calibrating the ADCs 51-54 of the electron-optical device (e.g. the electron beam tool 100). FIG. 6 is a diagram showing a set-up for pre-calibrating the ADCs 51-54. In some embodiments, the pre-calibration comprises using a test calibration current to adjust the ADC calibration settings to match prior to acquiring the SEM image data.

As shown in FIG. 6, an internal calibration current supply 56 may be selectively connected to the ADCs 51-54. The detector elements 145 may be controllably connected to the ADCs 51-54. In some embodiments, a controller is configured to selectively connect the internal calibration current supply 56 and the detector elements 145 to the ADCs 51-54. For example, switches 57 may be provided for controlling connection between the internal calibration current supply 56 and the ADCs 51-54 and between the detector elements 145 and the ADCs 51-54. As shown in FIG. 6, in some embodiments, the analog signals are operated on by one or more trans impedance amplifiers (TIAs) before reaching the ADCs 51-54.

As shown in FIG. 7, in some embodiments, the method comprises the pre-calibration step 310 of connecting the internal calibration current supply 56 to the ADCs 51-54. In pre-calibration step 312, the same signal is input into all of the ADCs 51-54. The detector elements 145 may be disconnected from the ADCs 51-54 during this time. When the internal calibration current supply 56 is connected to the ADCs 51-54, the configuration of the system is different compared to during a scan.

In pre-calibration step 314, image data output by the ADCs 51-54 is measured. The grey level output by each of the ADCs 51-54 is measured. This provides an indication of the extent to which the ADCs 51-54 are latched, i.e. the extent to which they give the same grey level value for the same electron signal input.

In pre-calibration step 316, at least one setting of at least one of the ADCs 51-54 is adjusted based on the measured image data. By adjusting the at least one setting, any difference between image data output by the ADCs 51-54 converted from a same signal may be reduced. The adjustment is for counteracting any mismatch between the ADCs 51-54. As shown by the arrow 147 in FIG. 6, the measurement of the grey levels output by the ADCs 51-54 is used for calibration of the ADCs 51-54. This is a feedback mechanism.

In some embodiments, one of the ADCs 51-54 is a reference ADC. For example, the second ADC 52 may be the reference ADC. In some embodiments, the at least one setting is changed for one or more of the other ADCs, i.e. the ADCs other than the reference ADC. For example, when the second ADC 52 is the reference ADC, then the at least one setting may be changed for at least one of the first ADC 51, the third ADC 53 and the fourth ADC 54. The second ADC 52 as the reference ADC may not be corrected. The other ADCs are corrected so as to match the reference ADC.

In some embodiments, the data order from the detector elements 145 to the ADCs is the first ADC 51 followed by the second ADC 52, followed by the third ADC 53, followed by the fourth ADC 54. In some embodiments, the reference ADC is the second ADC in the order. Alternatively, the reference ADC may be the first ADC, the third ADC or the fourth ADC.

The pre-calibration may lead to improved consistency of the grey level values output by the ADCs 51-54. The pre-calibration may reduce mismatches between the ADCs 51-54. Systematic differences between the ADCs 51-54 may remain after the pre-calibration. For example, the unenhanced SEM image 60 shown in FIG. 3 is generated from data accumulated after pre-calibration of the ADCs 51-54. Image artifacts may be present in the image data even after pre-calibration of the ADCs 51-54.

In particular, the test signal may not be sufficiently stable. The test signal is routed throughout the circuitry 50 to the different ADCs 51-54. As the test signal is routed, it may pick up disturbances. As a result, the different ADCs 51-54 may receive different versions of the test signal. This can lead to systematic errors in calibration of the ADCs 51-54 based on the test signal. Additionally, during calibration using the test signal, the configuration of the system is different compared to during a scan. In particular, the test signal is connected to the ADCs 51-54 while the detector elements 145 are disconnected from the ADCs 51-54. This difference in configuration may result in errors in calibration based on the test signal.

In some embodiments, the pre-calibration may be omitted from the method of enhancing image data. The pre-calibration may have previously been performed before the process of enhancing image data is performed. Alternatively, the pre-calibration of the ADCs 51-54 may not be performed at all.

As shown in FIG. 7, in some embodiments, the method of enhancing image data comprises data acquisition step 318 in which detector elements 145 are connected to the ADCs 51-54. In some embodiments, the controller selectively connects the detector elements 145 to the ADCs 51-54. This prepares the electron beam tool 100 for the performance of a scan of the sample. The internal calibration current supply 56 may be disconnected from the ADCs 51-54. This may be done by controlling the switches 57.

In data acquisition step 320, the electron beam tool 100 scans the sample (e.g. a wafer). An electron beam 143 of signal electrons (e.g. backscattered electrons and/or secondary electrons) is incident on the detector elements 145. The detector elements 145 detect signal electrons from locations of the sample. Analog signals corresponding to the detected electrons from the different locations are transferred to the ADCs 51-54. The analog signals may be input to the ADCs 51-54 in a repeating sequence.

For example, in some embodiments, a clock signal 58 is used to control timings of applying sequential analog signals from the detector elements 145 to the ADCs 51-54. The clock signal 58 is a repeating pattern over time t. A series of subsidiary clock signals 59 may be used for the second and subsequent ADCs in the repeating sequence of ADCs.

In some embodiments, the data acquisition steps 318, 320 may be omitted from the method of enhancing image data. The method may be performed on image data that has previously been generated. For example, the method may be performed on image data that has been stored in a memory.

As shown in FIG. 7, in some embodiments, the method of enhancing image data comprises enhancement step 322 of adjusting, for at least one of the ADCs, the distribution of image data output by the ADC so that the calculated at least one statistical values match across the distributions of image data output by the ADCs. This enhances the image data. For example, the digital signals output by the third ADC 53 may be adjusted so that the mean of the digital signals matches the mean of the digital signals output by the second ADC 52. This improves the image data, as shown from a comparison between FIG. 3 (the unenhanced SEM image 60) and FIG. 4 (the enhanced SEM image 66).

In some embodiments, the method of enhancing image data comprises the enhancement step 324 of generating an image from the enhanced image data. For example an image such as is shown in FIG. 4 may be produced.

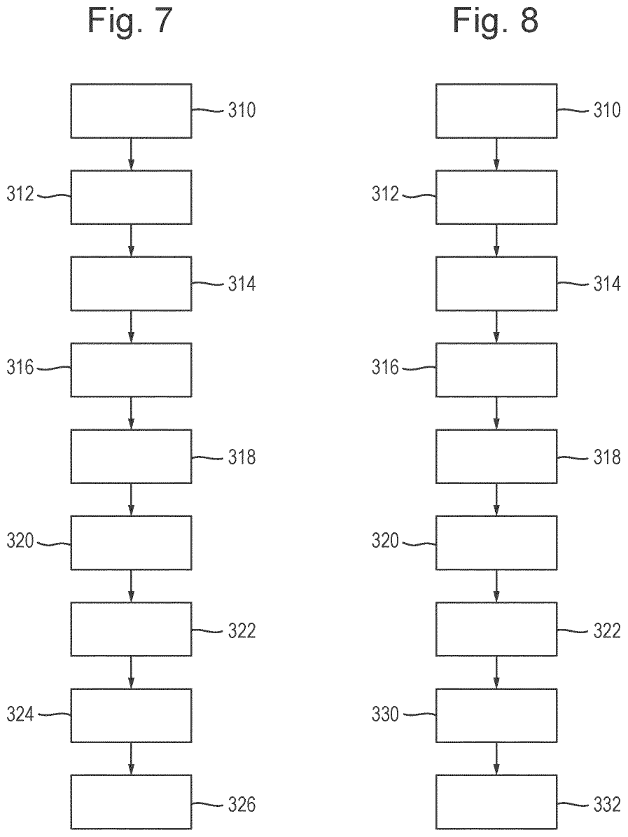

FIG. 8 is a process flow chart representing an exemplary method of calibrating ADCs 51-54. The method of calibrating ADCs 51-54 may comprise some of the same steps as the method of enhancing image data described in relation to FIG. 7. Further description of those steps is omitted so as to avoid redundant description.

In some embodiments, the method of calibrating ADCs 51-54 comprises calibration step 330 in which at least one statistical value (e.g. mean, standard deviation) is calculated from a distribution of the image data output by each of the ADCs 51-54.

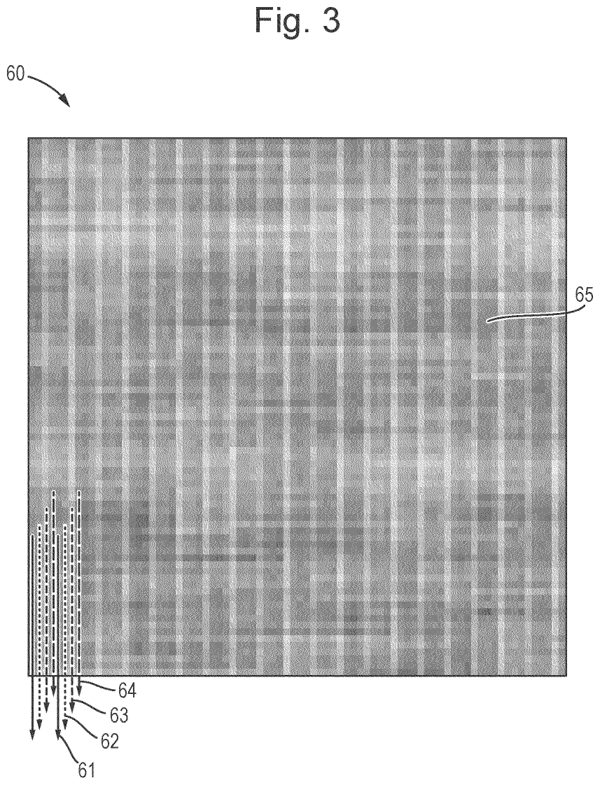

FIG. 5 is a graph showing the relationship between image data output by the reference ADC and the unenhanced image data output by one of the other ADCs. For example, in FIG. 5 the X axis represents the brightness value (or grey level value) of image data output by the second ADC 52, which is the reference ADC. The Y axis is the brightness values of image data output by the third ADC 53. Each point 70 on the graph is positioned based on the brightness values of adjacent pixels (i.e. adjacent locations on the sample). The unenhanced SEM image 60 may be considered to comprise a series of blocks of four pixels. Each block of four pixels consists of one pixel having a brightness value based on a digital signal from each of the four ADCs 51-54. Eight points 70 are shown in FIG. 5. In a typical scan there may be far more digital signals output.

FIG. 5 shows the second ADC average 71 which is an average grey level value from among the digital signals output by the second ADC 52. FIG. 5 shows the third ADC average 73, which is the average value of grey level values of digital signals output by the third ADC 53. FIG. 5 shows the second ADC standard deviation 72 which is the standard deviation of the grey levels of the digital signals output by the second ADC 52. FIG. 5 shows the third ADC standard deviation 74 which is the standard deviation of the grey levels of the digital signals output by the third ADC 53. These values may be calculated in enhancement step 322.

FIG. 5 shows an unenhanced data trend line 75 which is a trend line for the data points 70. The gradient of the trend line 75 is indicative of a gain mismatch between the second ADC 52 and the third ADC 53. In FIG. 5 the reference line 78 has a gradient of one and intercepts the Y axis at zero. If the second ADC 52 and the third ADC 53 had matching gains, then the gradient of the trend line 75 would be 1 (i.e. equal to the reference line 78).

In some embodiments, the method of calibrating ADCs comprises the calibration step 332 in which a gain mismatch and/or an offset mismatch is calculated for each of the ADCs 51, 53, 54 other than the reference ADC 52. In some embodiments, the gain mismatch is based on a ratio between a standard deviation of a distribution of image data output by an ADC other than the reference ADC and a standard deviation of a distribution of image data output by the reference ADC. For example, the gain mismatch for the third ADC 53 may be based on a ratio between a standard deviation of the image data output by the third ADC 53 and the standard deviation of the image data output by the second ADC 52. The gain mismatches for the ADCs may be calculated using the following equations.

In some embodiments, the method of calibrating ADCs comprises the calibration step 332 of changing at least one setting for at least one of the ADCs other than the reference ADC. For example, in some embodiments, the gain for an ADC other than the reference ADC is changed based on the gain mismatch.

In some embodiments, the ADC gain pivot point 76 (shown in FIG. 5) is at a grey level midpoint 82. In some embodiments, the grey level midpoint 82 corresponds to a grey level value that is in the middle of the possible range of grey level values. For example, when the grey level values can range from 0 to 255, then the grey level midpoint 82 may be a value of 128. When the gain of an ADC is adjusted, the effect on the trend line 75 shown in FIG. 5 is to rotate the trend line about the ADC gain pivot point 76.

In some embodiments, the calibration step 332 comprises calculating an offset mismatch. The offset mismatch is indicative of variation between an offset applied by the reference ADC and an offset applied by an ADC other than the reference ADC. The offset is a value that is added to the signal when converting the analog signal into the digital signal. As shown in FIG. 5, the trend line 75 is offset from the reference line 78, if there were no offset mismatch between the second ADC 52 and the third ADC 53, then the ADC gain pivot point 76 would be coincident with the reference line 78. Mean offset line 77 is offset from the reference line 78 by the difference 79 in averages.

As shown in FIG. 5, in some embodiments, the offset mismatch 81 is defined at a midpoint 82 of a range of possible values of image data output by the ADCs. By defining the offset mismatch 81 at the midpoint 82 (which may be the centre of the grey levels), the gain correction may have a minimum impact on the offset correction. The gain correction and the offset correction may be more independent from each other. This can help to simplify the adjustment of the settings (e.g. gain, offset) of the ADCs 51, 53, 54 other than the reference ADC.

In some embodiments, the offset mismatch 81 is dependent on a difference between a mean of a distribution of image data output by an ADC other than the reference ADC and a mean of a distribution of image data output by the reference ADC. For example, the offset mismatch for the third ADC 53 may be dependent on the difference between the mean of image data output by the third ADC 53 and the mean of the image data output by the second ADC 52. This difference 79 in means is indicated in FIG. 5. As shown in FIG. 5, the difference 79 in means may be different from the offset mismatch 81. This is because the offset mismatch 81 may be defined at the midpoint 82 of the range of possible values of image data output by the ADCs.

In some embodiments, the offset mismatch 81 is dependent on a gain mismatch indicative of variation between the gain applied by the reference ADC and the gain applied by the ADC other than the reference ADC. For example, the offset mismatch 81 for the third ADC 53 may be dependent on a gain mismatch for the third ADC 53. The sum of the difference 79 in means and this additional term 80 determines the overall offset mismatch 81 at the midpoint 82. The offset mismatches for the ADCs other than the reference ADC may be calculated using the formulas below.

In the calibration step 332, the offset for an ADC other than the reference ADC may be changed based on the offset mismatch 81.

In some embodiments, calibration of the ADCs 51-54 may be repeated. For example, the ADCs 51-54 may be used to output further image data after changing the at least one setting. The steps of calculating at least one statistical value and determining at least one distribution adjustment may be repeated for the further image data. The step of changing at least one setting may be repeated based on the further determined at least one distribution adjustment.

For example, steps 320, 322, 330 and 332 may be repeated. This may be an iterative process. With each iteration, the mismatch between the ADCs 51-54 may be reduced.

As mentioned above, pre-calibration may be performed. The pre-calibration is based on applying the same signal to all of the ADCs 51-54. By following the pre-calibration using the single test signal, the number of iterations needed to achieve the required level of matching between the ADCs 51-54 may be reduced. The pre-calibration step pre-calibrates the ADCs 51-54 independently of the structures of the sample. However, the pre-calibration step is not essential.

In some embodiments, the method uses the average and the spread (e.g. standard deviation) of the grey level values in the SEM image data to determine the mismatch of the separate ADC readings. The different ADCs 51-54 output digital signals that correspond to different locations of the sample. Some of the differences in digital signals output by the different ADCs 51-54 may correctly reflect two differences in structures of the sample at the different locations. There is only a small average image position difference of the separate ADC readings. As a result, a perfectly matching set of ADCs is expected to give almost exactly the same average and standard deviation of their image data.

A gain difference between ADCs would result in the spread (deviation) mismatch. By calculating the gain mismatch, any gain difference can be reduced. An offset difference would lead to a mismatch of the average values output by the different ADCs. By calculating the average values, the offset difference can be reduced by adjusting the offset based in part on the calculated average values.

When four ADCs 51-54 are used, there may be six calibration parameters to be adjusted. For each of the three ADCs that is not the reference ADC, the two parameters of gain and offset may be adjusted.

A typical SEM image may be expected to contain a large number of pixels, for example at least 250,000. A typical SEM image is expected to contain some signal contrast. As a result, the statistical values such as the average and spread are expected to allow for accurate calibration of the image data and the ADCs.

In some embodiments, a charge particle-optical device (e.g. an electron-optical device such as the electron beam tool 100) is configured to direct a charge particle beam (e.g. an electron beam) towards a sample location. Signal charge particles (e.g. signal electrons) are generated in response to the charge particle beam.

In some embodiments, the charged particle-optical device comprises an array of sensing elements (e.g. detector elements 145) configured to generate electrical signals in response to incident signal charged particles from the sample location. In some embodiments, the charge particle-optical device comprises a plurality of ADCs 51-54 configured to convert the electrical signals into image data. The ADCs may be comprised in the detector 144. Alternatively, the ADCs 51-54 may be provided separately from the detector 144. For example, the ADCs 51-54 may be provided in a separate image processing unit.

In some embodiments, the charged particle-optical device comprises a controller 109 configured to process the image data. In some embodiments, the controller 109 is configured to calculate, for each of the ADCs 51-54, at least one statistical value from a distribution of the image data output by the ADC. In some embodiments, the controller is configured to determine at least one distribution adjustment required for the calculated at least one statistical values to match across the distributions of image data output by the ADCs.

In some embodiments, the controller 109 is configured to adjust, for at least one of the ADCs, the distribution of image data so as to match a calculated statistical value across the distributions of image data output by the ADCs. This enhances the image data.

In some embodiments, the controller is configured to change at least one setting of at least one of the ADCs based on the calculated at least one statistical value so as to compensate for any mismatch between the ADCs.

In some embodiments, a non-transitory computer readable medium stores instructions for a processor of a controller (e.g. the controller 109) to carry out a method as described above.

Exemplary embodiments of the present disclosure are set out in the following numbered clauses:

1. A method for processing image data of charged particles detected from a sample output by a plurality of analog-to-digital converters, ADCs, the method comprising:
calculating, for each of the ADCs, at least one statistical value from a distribution of the image data output by the ADC; and
determining at least one distribution adjustment required for the calculated at least one statistical values to match across the distributions of image data output by the ADCs.
   2. The method of clause 1 comprising:
changing at least one setting of at least one of the ADCs based on the determined distribution adjustment.
   3. The method of clause 2, wherein the at least one setting comprises at least one setting selected from:
a gain applied by the ADC when converting an incoming signal into image data to be output;
and an offset applied by the ADC when converting an incoming signal into image data to be output.
   4. The method of clause 3, wherein one of the ADCs is a reference ADC and the at least one setting is changed for the at least one ADC other than the reference ADC.
   5. The method of clause 4, wherein the gain for an ADC other than the reference ADC is changed based on a gain mismatch indicative of variation between the gain applied by the reference ADC and the gain applied by the ADC other than the reference ADC.
   6. The method of clause 5, wherein the gain mismatch is based on a ratio between a standard deviation of a distribution of image data output by an ADC other than the reference ADC and a standard deviation of a distribution of image data output by the reference ADC.
   7. The method of any of clauses 4-6, wherein the offset for an ADC other than the reference ADC is changed based on an offset mismatch indicative of variation between the offset applied by the reference ADC and the offset applied by the ADC other than the reference ADC.
   8. The method of clause 7, wherein the offset mismatch is dependent on a difference between a mean of a distribution of image data output by an ADC other than the reference ADC and a mean of a distribution of image data output by the reference ADC.
   9. The method of clause 7 or 8, wherein the offset mismatch is defined at a midpoint of a range of possible values of image data output by the ADCs.
   10. The method of clause 9, wherein the offset mismatch is dependent on a gain mismatch indicative of variation between the gain applied by the reference ADC and the gain applied by the ADC other than the reference ADC.
   11. The method of any of clauses 2-10 comprising:
using the ADCs to output further image data after changing the at least one setting.
   12. The method of clause 11 comprising:
repeating the calculating and determining steps for the further image data.
   13. The method of clause 12 comprising:
repeating the changing step for the repeated determining step.
   14. The method of any preceding clause comprising:
calibrating the ADCs by:
inputting a same signal into all of the ADCs;
measuring image data output by the ADCs; and
adjusting at least one setting of at least one of the ADCs based on the measured image data, so as to reduce any difference between image data output by the ADCs converted from a same signal.
   15. The method of clause 14, wherein the calibrating step is performed before the calculating and determining steps.
   16. The method of any preceding clause comprising:
performing the at least one determined distribution adjustment so as to provide adjusted image data.
   17. The method of any preceding clause, wherein the at least one statistical value comprises at least one of a mean and a standard deviation.
   18. The method of any preceding clause, wherein the image data output by the ADCs are of a region of a sample scanned during a single scanning procedure.
   19. The method of any preceding clause, wherein the image data are output by the ADCs according to a repeated sequence of the ADCs.
   20. A non-transitory computer readable medium that stores instructions for a processor of a controller to carry out a method for processing image data of charged particles detected from a sample output by a plurality of analog-to-digital converters, ADCs, the method comprising:
calculating, for each of the ADCs, at least one statistical value from a distribution of image data output by the ADC; and
determining at least one distribution adjustment required for the calculated at least one statistical values to match across the distributions of image data output by the ADCs.
   21. The non-transitory computer readable medium of clause 20, the method comprising: instructing a change of at least one setting of at least one of the ADCs based on the determined distribution adjustment.
   22. The non-transitory computer readable medium of clause 21, wherein the at least one setting comprises at least one setting selected from:
a gain applied by the ADC when converting an incoming signal into image data to be output; and
an offset applied by the ADC when converting an incoming signal into image data to be output.
   23. The non-transitory computer readable medium of clause 22, wherein one of the ADCs is a reference ADC and the at least one setting is instructed to be changed for the at least one ADC other than the reference ADC.
   24. The non-transitory computer readable medium of clause 23, wherein the gain for an ADC other than the reference ADC is instructed to be changed based on a gain mismatch indicative of variation between the gain applied by the reference ADC and the gain applied by the ADC other than the reference ADC.
   25. The non-transitory computer readable medium of clause 19, wherein the gain mismatch is based on a ratio between a standard deviation of a distribution of image data output by an ADC other than the reference ADC and a standard deviation of a distribution of image data output by the reference ADC.
   26. The non-transitory computer readable medium of any of clauses 23-25, wherein the offset for an ADC other than the reference ADC is instructed to be changed based on an offset mismatch indicative of variation between the offset applied by the reference ADC and the offset applied by the ADC other than the reference ADC.
   27. The non-transitory computer readable medium of clause 26, wherein the offset mismatch is dependent on a difference between a mean of a distribution of image data output by an ADC other than the reference ADC and a mean of a distribution of image data output by the reference ADC.
   28. The non-transitory computer readable medium of clause 26 or 27, wherein the offset mismatch is defined at a midpoint of a range of possible values of image data output by the ADCs.
   29. The non-transitory computer readable medium of clause 28, wherein the offset mismatch is dependent on a gain mismatch indicative of variation between the gain applied by the reference ADC and the gain applied by the ADC other than the reference ADC.
   30. The non-transitory computer readable medium of any of clauses 21-29, the method comprising: causing the ADCs to output further image data after instructing the change of the at least one setting.
   31. The non-transitory computer readable medium of clause 30, the method comprising: repeating the calculating and determining steps for the further image data.
   32. The non-transitory computer readable medium of clause 31, the method comprising: repeating the instructing step for the repeated determining step.
   33. The non-transitory computer readable medium of any of clauses 20-32, the method comprising:
calibrating the ADCs by:
   inputting a same signal into all of the ADCs;
   measuring image data output by the ADCs; and
   instructing an adjustment of at least one setting of at least one of the ADCs based on the measured image data, so as to reduce any difference between image data output by the ADCs converted from a same signal.
      34. The non-transitory computer readable medium of clause 33, wherein the calibrating step is performed before the calculating and determining steps.
      35. The non-transitory computer readable medium of any of clauses 20-34 comprising:
performing the at least one determined distribution adjustment so as to provide adjusted image data.
   36. The non-transitory computer readable medium of any of clauses 20-35, wherein the at least one statistical value comprises at least one of a mean and a standard deviation.
   37. The non-transitory computer readable medium of any of clauses 20-36, wherein the image data output by the ADCs are of a region of a sample scanned during a single scanning procedure.
   38. The non-transitory computer readable medium of any of clauses 20-37, wherein the image data are output by the ADCs according to a repeated sequence of the ADCs.
   39. A charged particle-optical device configured to direct a charged particle beam towards a sample location so that signal charged particles are generated in response to the charged particle beam, the charged particle-optical device comprising:
an array of sensing elements configured to generate electrical signals in response to incident signal charged particles from the sample location;
a plurality of analog-to-digital converters, ADCs, configured to convert the electrical signals into image data; and
a controller configured to process the image data by:
   calculating, for each of the ADCs, at least one statistical value from a distribution of the image data output by the ADC; and
      determining at least one distribution adjustment required for the calculated at least one statistical values to match across the distributions of image data output by the ADCs.
         40. A method of enhancing image data generated by a charged particle-optical device comprising:
providing, for each of a plurality of analog-to-digital converters, ADCs, image data of charged particles detected from a sample output by the ADC;
calculating, for each of the ADCs, at least one statistical value from a distribution of the image data output by the ADC; and
adjusting, for at least one of the ADCs, the distribution of image data output by the ADC so that the calculated at least one statistical values match across the distributions of image data output by the ADCs, so as to enhance the image data.
   41. The method of clause 40, wherein the image data is scanning electron microscope image data.
   42. The method of clause 40 or 41 comprising:
generating an image from the enhanced image data.
   43. A non-transitory computer readable medium that stores instructions for a processor of a controller to carry out a method for enhancing image data of charged particles detected from a sample output by a plurality of analog-to-digital converters, ADCs, the method comprising:
calculating, for each of the ADCs, at least one statistical value from a distribution of the image data output by the ADC; and
adjusting, for at least one of the ADCs, the distribution of image data output by the ADC so that the calculated at least one statistical values match across the distributions of image data output by the ADCs, so as to enhance the image data.
   44. The non-transitory computer readable medium of clause 43, wherein the image data is scanning electron microscope image data.
   45. The non-transitory computer readable medium of clause 43 or 44, the method comprising:
generating an image from the enhanced image data.
   46. A charged particle-optical device configured to direct a charged particle beam towards a sample location so that signal charged particles are generated in response to the charged particle beam, the charged particle-optical device comprising:
an array of sensing elements configured to generate electrical signals in response to incident signal charged particles from the sample location;
a plurality of analog-to-digital converters, ADCs, configured to convert the electrical signals into image data; and
a controller configured to enhance the image data by:
   calculating, for each of the ADCs, at least one statistical value from a distribution of the image data output by the ADC; and
   adjusting, for at least one of the ADCs, the distribution of image data output by the ADC so that the calculated at least one statistical values match across the distributions of image data output by the ADCs, so as to enhance the image data.
      47. A method of calibrating analog-to-digital converters, ADCs, of a charged particle-optical device comprising:
providing, for each of the ADCs, image data of charged particles detected from a sample output by the ADC;
calculating, for each of the ADCs, at least one statistical value from a distribution of the image data output by the ADC; and
changing at least one setting of at least one of the ADCs based on the calculated at least one statistical values so as to compensate for any mismatch between the at least one statistical value of the ADCs.
   48. The method of clause 47, wherein the charged particle-optical device is comprised in a scanning electron microscope.
   49. The method of clause 47 or 48 comprising:
outputting, from each of the ADCs, further image data of charged particles detected from a sample after changing the at least one setting of at least one of the ADCs; and
repeating the calculating and changing steps for the further image data.
   50. The method of any of clauses 47-49 comprising:
pre-calibrating the ADCs before the providing step by:
   inputting a same signal into all of the ADCs;
   measuring image data output by the ADCs; and
   adjusting at least one setting of at least one of the ADCs based on the measured image data, so as to reduce any difference between image data output by the ADCs converted from a same signal.
      51. A non-transitory computer readable medium that stores instructions for a processor of a controller to carry out a method for calibrating a plurality of analog-to-digital converters, ADCs, of a charged particle-optical device, the method comprising: calculating, for each of the ADCs, at least one statistical value from a distribution of image data of charged particles detected from a sample output by the ADC; and
instructing a change of at least one setting of at least one of the ADCs based on the calculated at least one statistical values so as to compensate for any mismatch between the at least one statistical value of the ADCs.
   52. The non-transitory computer readable medium of clause 51, wherein the charged particle-optical device is comprised in a scanning electron microscope.
   53. The non-transitory computer readable medium of clause 51 or 52, the method comprising:
obtaining, from each of the ADCs, further image data of charged particles detected from a sample after changing the at least one setting of at least one of the ADCs; and
repeating the calculating and changing steps for the further image data.
   54. The non-transitory computer readable medium of any of clauses 51-53, the method comprising:
pre-calibrating the ADCs before the providing step by:
   inputting a same signal into all of the ADCs;
   measuring image data output by the ADCs; and
   instructing an adjustment of at least one setting of at least one of the ADCs based on the measured image data, so as to reduce any difference between image data output by the ADCs converted from a same signal.
      55. A charged particle-optical device configured to direct a charged particle beam towards a sample location so that signal charged particles are generated in response to the charged particle beam, the charged particle-optical device comprising:
an array of sensing elements configured to generate electrical signals in response to incident signal charged particles from the sample location;
a plurality of analog-to-digital converters, ADCs, configured to convert the electrical signals into image data; and
a controller configured to calibrate the ADCs by:
   calculating, for each of the ADCs, at least one statistical value from a distribution of the image data output by the ADC; and
   changing at least one setting of at least one of the ADCs based on the calculated at least one statistical values so as to compensate for any mismatch between the at least one statistical value of the ADCs.
      56. A method for changing a setting of at least one analog-to-digital converter, ADC, of a plurality of ADCs, the method comprising:
receiving, for each ADC, at least one statistical value that was calculated from a distribution of the image data output by the ADC; and
changing at least one setting of the at least one ADC based on a distribution adjustment that was determined as required for the calculated at least one statistical values to match across the distributions of image data output by the ADCs.
   57. The method of clause 56, wherein the at least one setting comprises at least one setting selected from:
a gain applied by the ADC when converting an incoming signal into image data to be output; and an offset applied by the ADC when converting an incoming signal into image data to be output.
   58. The method of clause 57, wherein one of the ADCs is a reference ADC and the at least one setting is changed for the at least one ADC other than the reference ADC.
   59. The method of clause 58, wherein the gain for an ADC other than the reference ADC is changed based on a gain mismatch indicative of variation between the gain applied by the reference ADC and the gain applied by the ADC other than the reference ADC.
   60. The method of clause 59, wherein the gain mismatch is based on a ratio between a standard deviation of a distribution of image data output by an ADC other than the reference ADC and a standard deviation of a distribution of image data output by the reference ADC.
   61. The method of any of clauses 58-60, wherein the offset for an ADC other than the reference ADC is changed based on an offset mismatch indicative of variation between the offset applied by the reference ADC and the offset applied by the ADC other than the reference ADC.
   62. The method of clause 61, wherein the offset mismatch is dependent on a difference between a mean of a distribution of image data output by an ADC other than the reference ADC and a mean of a distribution of image data output by the reference ADC.
   63. The method of clause 61 or 62, wherein the offset mismatch is defined at a midpoint of a range of possible values of image data output by the ADCs.
   64. The method of clause 63, wherein the offset mismatch is dependent on a gain mismatch indicative of variation between the gain applied by the reference ADC and the gain applied by the ADC other than the reference ADC.
   65. The method of any of clauses 56-64 comprising:
causing the ADCs to output further distributions of image data after changing the at least one setting.
   66. The method of clause 65 comprising:
repeating the changing step based on a further distribution adjustment that was determined as required for the calculated at least one statistical values to match across the further distributions of image data output by the ADCs.
   67. The method of any of clauses 56-66 comprising:
calibrating the ADCs by:
   inputting a same signal into all of the ADCs;
   measuring image data output by the ADCs; and
   adjusting at least one setting of at least one of the ADCs based on the measured image data, so as to reduce any difference between image data output by the ADCs converted from a same signal.
      68. The method of clause 67, wherein the calibrating step is performed before the receiving and changing steps.
      69. The method of any of clauses 56-68, wherein the at least one statistical value comprises at least one of a mean and a standard deviation.
      70. The method of any of clauses 56-69, wherein the image data output by the ADCs are of a region of a sample scanned during a single scanning procedure.
      71. The method of any of clauses 56-70, wherein the image data are output by the ADCs according to a repeated sequence of the ADCs.
      72. A non-transitory computer readable medium that stores instructions for a processor of a controller to carry out a method for instructing a change of a setting of at least one analog-to-digital converter, ADC, of a plurality of ADCs, the method comprising:
receiving, for each ADC, at least one statistical value that was calculated from a distribution of the image data output by the ADC; and
instructing a change of at least one setting of the at least one ADC based on a distribution adjustment that was determined as required for the calculated at least one statistical values to match across the distributions of image data output by the ADCs.
   73. The non-transitory computer readable medium of clause 72, wherein the at least one setting comprises at least one setting selected from:
a gain applied by the ADC when converting an incoming signal into image data to be output;
and an offset applied by the ADC when converting an incoming signal into image data to be output.
   74. The non-transitory computer readable medium of clause 73, wherein one of the ADCs is a reference ADC and the at least one setting is instructed to be changed for the at least one ADC other than the reference ADC.
   75. The non-transitory computer readable medium of clause 74, wherein the gain for an ADC other than the reference ADC is instructed to be changed based on a gain mismatch indicative of variation between the gain applied by the reference ADC and the gain applied by the ADC other than the reference ADC.
   76. The non-transitory computer readable medium of clause 75, wherein the gain mismatch is based on a ratio between a standard deviation of a distribution of image data output by an ADC other than the reference ADC and a standard deviation of a distribution of image data output by the reference ADC.
   77. The non-transitory computer readable medium of any of clauses 74-76, wherein the offset for an ADC other than the reference ADC is instructed to be changed based on an offset mismatch indicative of variation between the offset applied by the reference ADC and the offset applied by the ADC other than the reference ADC.
   78. The non-transitory computer readable medium of clause 77, wherein the offset mismatch is dependent on a difference between a mean of a distribution of image data output by an ADC other than the reference ADC and a mean of a distribution of image data output by the reference ADC.
   79. The non-transitory computer readable medium of clause 77 or 78, wherein the offset mismatch is defined at a midpoint of a range of possible values of image data output by the ADCs.
   80. The non-transitory computer readable medium of clause 79, wherein the offset mismatch is dependent on a gain mismatch indicative of variation between the gain applied by the reference ADC and the gain applied by the ADC other than the reference ADC.
   81. The non-transitory computer readable medium of any of clauses 72-80, the method comprising:
causing the ADCs to output further distributions of image data after changing the at least one setting.
   82. The non-transitory computer readable medium of clause 81, the method comprising:
repeating the instructing step based on a further distribution adjustment that was determined as required for the calculated at least one statistical values to match across the further distributions of image data output by the ADCs.
   83. The non-transitory computer readable medium of any of clauses 72-82, the method comprising:
calibrating the ADCs by:
   inputting a same signal into all of the ADCs;
   measuring image data output by the ADCs; and
   instructing an adjustment of at least one setting of at least one of the ADCs based on the measured image data, so as to reduce any difference between image data output by the ADCs converted from a same signal.
      84. The non-transitory computer readable medium of clause 83, wherein the calibrating step is performed before the receiving and changing steps.
      85. The non-transitory computer readable medium of any of clauses 72-84, wherein the at least one statistical value comprises at least one of a mean and a standard deviation.
      86. The non-transitory computer readable medium of any of clauses 72-85, wherein the image data output by the ADCs are of a region of a sample scanned during a single scanning procedure.
      87. The non-transitory computer readable medium of any of clauses 72-86, wherein the image data are output by the ADCs according to a repeated sequence of the ADCs.
      88. A charged particle-optical device configured to direct a charged particle beam towards a sample location so that signal charged particles are generated in response to the charged particle beam, the charged particle-optical device comprising:
an array of sensing elements configured to generate electrical signals in response to incident signal charged particles from the sample location;
a plurality of analog-to-digital converters, ADCs, configured to convert the electrical signals into image data; and
a controller configured to process the image data by:
   receiving, for each ADC, at least one statistical value that was calculated from a distribution of the image data output by the ADC; and
   changing at least one setting of the at least one ADC based on a distribution adjustment that was determined as required for the calculated at least one statistical values to match across the distributions of image data output by the ADCs.
      89. A method of enhancing an image that can be generated based on image data generated by a charged particle-optical device comprising:
providing, for each of a plurality of analog-to-digital converters, ADCs, image data of charged particles detected from a sample output by the ADC;
receiving, for each ADC, at least one statistical value that was calculated from a distribution of the image data output by the ADC; and
adjusting, for at least one of the ADCs, the distribution of image data output by the ADC so that the calculated at least one statistical values match across the distributions of image data output by the ADCs, so as to enhance an image that can be generated based on the image data.
   90. The method of clause 89, wherein the image data is scanning electron microscope image data.
   91. The method of clause 89 or 90 comprising:
generating the enhanced image from the image data.
   92. A non-transitory computer readable medium that stores instructions for a processor of a controller to carry out a method for enhancing an image that can be generated based on image data of charged particles detected from a sample output by a plurality of analog-to-digital converters, ADCs, the method comprising:
receiving, for each ADC, at least one statistical value that was calculated from a distribution of the image data output by the ADC; and
adjusting, for at least one of the ADCs, the distribution of image data output by the ADC so that the calculated at least one statistical values match across the distributions of image data output by the ADCs, so as to enhance an image that can be generated based on the image data.
   93. The non-transitory computer readable medium of clause 92, wherein the image data is scanning electron microscope image data.
   94. The non-transitory computer readable medium of clause 92 or 93 comprising:
generating the enhanced image from the image data.
   95. A charged particle-optical device configured to direct a charged particle beam towards a sample location so that signal charged particles are generated in response to the charged particle beam, the charged particle-optical device comprising:
an array of sensing elements configured to generate electrical signals in response to incident signal charged particles from the sample location;
a plurality of analog-to-digital converters, ADCs, configured to convert the electrical signals into image data; and
a controller configured to enhance an image that can be generated based on the image data by:
   receiving, for each ADC, at least one statistical value that was calculated from a distribution of the image data output by the ADC; and
   adjusting, for at least one of the ADCs, the distribution of image data output by the ADC so that the calculated at least one statistical values match across the distributions of image data output by the ADCs, so as to enhance an image that can be generated based on the image data.
      96. A method of calibrating analog-to-digital converters, ADCs, of a charged particle-optical device comprising:
providing, for each of the ADCs, image data of charged particles detected from a sample output by the ADC;
receiving, for each ADC, at least one statistical value that was calculated from a distribution of the image data output by the ADC; and
changing at least one setting of at least one of the ADCs based on the calculated at least one statistical values so as to compensate for any mismatch between the at least one statistical value of the ADCs.
   97. The method of clause 96, wherein the charged particle-optical device is comprised in a scanning electron microscope.
   98. The method of clause 96 or 97 comprising:
outputting, from each of the ADCs, further distributions of image data of charged particles detected from a sample after changing the at least one setting of at least one of the ADCs; and
repeating the changing step based on a further distribution adjustment that was determined as required for the calculated at least one statistical values to match across the further distributions of image data output by the ADCs.
   99. The method of any of clauses 97-98 comprising:
pre-calibrating the ADCs before the providing step by:
   inputting a same signal into all of the ADCs;
   measuring image data output by the ADCs; and
   adjusting at least one setting of at least one of the ADCs based on the measured image data, so as to reduce any difference between image data output by the ADCs converted from a same signal.
      100. A non-transitory computer readable medium that stores instructions for a processor of a controller to carry out a method for calibrating a plurality of analog-to-digital converters, ADCs, of a charged particle-optical device, the method comprising: receiving, for each ADC, at least one statistical value that was calculated from a distribution of the image data output by the ADC; and
instructing a change of at least one setting of at least one of the ADCs based on the calculated at least one statistical values so as to compensate for any mismatch between the at least one statistical value of the ADCs.
   101. The non-transitory computer readable medium of clause 100, wherein the charged particle-optical device is comprised in a scanning electron microscope.
   102. The non-transitory computer readable medium of clause 100 or 101, the method comprising:
obtaining, from each of the ADCs, further distributions of image data of charged particles detected from a sample after changing the at least one setting of at least one of the ADCs; and
repeating the instructing step based on a further distribution adjustment that was determined as required for the calculated at least one statistical values to match across the further distributions of image data output by the ADCs.
   103. The non-transitory computer readable medium of any of clauses 100-102, the method comprising:
pre-calibrating the ADCs before the providing step by:
   inputting a same signal into all of the ADCs;
   measuring image data output by the ADCs; and
   instructing an adjustment of at least one setting of at least one of the ADCs based on the measured image data, so as to reduce any difference between image data output by the ADCs converted from a same signal.
      104. A charged particle-optical device configured to direct a charged particle beam towards a sample location so that signal charged particles are generated in response to the charged particle beam, the charged particle-optical device comprising:
an array of sensing elements configured to generate electrical signals in response to incident signal charged particles from the sample location;
a plurality of analog-to-digital converters, ADCs, configured to convert the electrical signals into image data; and
a controller configured to calibrate the ADCs by:
   receiving, for each ADC, at least one statistical value that was calculated from a distribution of the image data output by the ADC; and
   changing at least one setting of at least one of the ADCs based on the calculated at least one statistical values so as to compensate for any mismatch between the at least one statistical value of the ADCs.

A non-transitory computer readable medium may be provided that stores instructions for a processor of a controller (e.g., the controller 109 of FIG. 1) to carry out image inspection, image acquisition, activating charged-particle source, adjusting electrical excitation of stigmators, adjusting landing energy of electrons, adjusting objective lens excitation, adjusting secondary electron detector position and orientation, stage motion control, beam separator excitation, applying scan deflection voltages to beam deflectors, receiving and processing data associated with signal information from electron detectors, configuring an electrostatic element, detecting signal electrons, adjusting the control electrode potential, adjusting the voltages applied to the electron source, extractor electrode, and the sample, etc. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, other embodiments of the invention will be apparent to those skilled in the art from consideration of the specification and practice of the technology disclosed herein. It is intended that the specification and examples be considered as exemplary only, with a true scope and spirit of the invention being indicated by the following claims.

The descriptions above are intended to be illustrative, not limiting. Thus, it will be apparent to one skilled in the art that modifications may be made as described without departing from the scope of the claims set out below.

1. A charged particle-optical device configured to direct a charged particle beam towards a sample location so that signal charged particles are generated in response to the charged particle beam, the charged particle-optical device comprising:
an array of sensing elements configured to generate electrical signals in response to incident signal charged particles from the sample location;
a plurality of analog-to-digital converters (ADCs) configured to convert the electrical signals into image data; and
a controller configured to process the image data by:
receiving, for each ADC, at least one statistical value that was calculated from a distribution of the image data output by the ADC; and
changing at least one setting of the at least one ADC based on a distribution adjustment that was determined as required for the calculated at least one statistical values to match across the distributions of image data output by the ADCs.

2. The charged particle-optical device of claim 1, wherein the at least one setting comprises at least one setting selected from:
a gain applied by the ADC when converting an incoming signal into image data to be output; and
an offset applied by the ADC when converting an incoming signal into image data to be output.

3. The charged particle-optical device of claim 2, wherein one of the ADCs is a reference ADC and the controller is configured to change the at least one setting for the at least one ADC other than the reference ADC.

4. The charged particle-optical device of claim 3, wherein the controller is configured to change the gain for an ADC other than the reference ADC based on a gain mismatch indicative of variation between the gain applied by the reference ADC and the gain applied by the ADC other than the reference ADC.

5. The charged particle-optical device of claim 4, wherein the gain mismatch is based on a ratio between a standard deviation of a distribution of image data output by an ADC other than the reference ADC and a standard deviation of a distribution of image data output by the reference ADC.

6. The charged particle-optical device of claim 3, wherein the controller is configured to change the offset for an ADC other than the reference ADC based on an offset mismatch indicative of variation between the offset applied by the reference ADC and the offset applied by the ADC other than the reference ADC.

7. The charged particle-optical device of claim 6, wherein the offset mismatch is dependent on a difference between a mean of a distribution of image data output by an ADC other than the reference ADC and a mean of a distribution of image data output by the reference ADC.

8. The charged particle-optical device of claim 6, wherein the offset mismatch is defined at a midpoint of a range of possible values of image data output by the ADCs.

9. The charged particle-optical device of claim 8, wherein the offset mismatch is dependent on a gain mismatch indicative of variation between the gain applied by the reference ADC and the gain applied by the ADC other than the reference ADC.

10. The charged particle-optical device of claim 1, wherein the controller is configured to cause the ADCs to output further distributions of image data after changing the at least one setting.

11. The charged particle-optical device of claim 10, wherein the controller is configured to repeat the changing based on a further distribution adjustment that was determined as required for the calculated at least one statistical values to match across the further distributions of image data output by the ADCs.

12. The charged particle-optical device of claim 1, wherein the controller is configured to calibrate the ADCs by:
inputting a same signal into all of the ADCs;
measuring image data output by the ADCs; and
adjusting at least one setting of at least one of the ADCs based on the measured image data, so as to reduce any difference between image data output by the ADCs converted from a same signal.

13. The charged particle-optical device of claim 12, wherein the controller is configured to perform the calibration before the receiving and the changing.

14. The charged particle-optical device of claim 1, wherein the at least one statistical value comprises at least one of a mean and a standard deviation.

15. A method for processing image data of charged particles detected from a sample output by a plurality of analog-to-digital converters, ADCs, the method comprising:
calculating, for each of the ADCs, at least one statistical value from a distribution of the image data output by the ADC; and
determining at least one distribution adjustment required for the calculated at least one statistical values to match across the distributions of image data output by the ADCs.

16. A non-transitory computer readable medium that stores instructions for one or more processors of a device to perform operations for processing image data of charged particles detected from a sample output by a plurality of analog-to-digital converters, ADCs, the operations comprising:
calculating, for each of the ADCs, at least one statistical value from a distribution of image data output by the ADC; and
determining at least one distribution adjustment required for the calculated at least one statistical values to match across the distributions of image data output by the ADCs.

17. The non-transitory computer readable medium of claim 16, the operations comprising:
instructing a change of at least one setting of at least one of the ADCs based on the determined distribution adjustment.

18. The non-transitory computer readable medium of claim 17, wherein the at least one setting comprises at least one setting selected from:
a gain applied by the ADC when converting an incoming signal into image data to be output; and
an offset applied by the ADC when converting an incoming signal into image data to be output.

19. The non-transitory computer readable medium of claim 18, wherein one of the ADCs is a reference ADC and the at least one setting is instructed to be changed for the at least one ADC other than the reference ADC.

20. The non-transitory computer readable medium of claim 19, wherein the gain for an ADC other than the reference ADC is instructed to be changed based on a gain mismatch indicative of variation between the gain applied by the reference ADC and the gain applied by the ADC other than the reference ADC.
